(19) United States
(12) Patent Application Publication
(10) Pub. No.: US 2009/0197370 A1
(43) Pub. Date: Aug. 6, 2009

(54) Method and apparatus for manufacturing semiconductor device

(75) Inventors: Yosuke Katsura, Kanagawa (JP); Ichiro Saisho, Fukuoka (JP); Rika Iwanami, Fukuoka (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/320,399

(22) Filed: Jan. 26, 2009

(30) Foreign Application Priority Data
Feb. 4, 2008 (JP) 23733/2008

(51) Int. Cl. H01L 21/60; B28B 17/00

(52) U.S. Cl. 438/108; 425/155; 257/E21.511

(57) ABSTRACT

There is provided a method and an apparatus for manufacturing a semiconductor device having a lidless and highly reliable flip-chip structure. The method for manufacturing a semiconductor device wherein an underfill resin is filled in a space between a substrate and a semiconductor chip includes injecting a first underfill resin in said space under a first injecting condition; specifying a location where the fillet height of the underfill resin formed on the side of said semiconductor chip does not meet a prescribed standard; and injecting a second underfill resin in a location where the fillet height does not meet the prescribed standard under a second injecting condition. Since the fillet heights can uniformly meet the prescribed standard, the concentration of stress can be avoided, and a semiconductor device having a lidless and highly reliable flip-chip structure can be manufactured.

### BACKGROUND OF THE INVENTION

1. Field of the Invention

The present invention relates to a method and an apparatus for manufacturing a semiconductor device that has a flip-chip structure.

2. Description of the Related Art

With the intensifying price competition of semiconductor devices in recent years, cost reduction has been strongly requested. To meet the request, a semiconductor device having a flip-chip structure, in which a lid 18 and a stiffener 17, which were equipped to conventional semiconductor devices having a flip-chip structure, are removed (hereafter referred to as a “lidless structure”) wad developed. FIG. 1 is a schematic diagram showing a conventional semiconductor device that has a flip-chip structure; and FIG. 2 is a schematic diagram showing a semiconductor device that has a lidless structure.

Documents related to conventional flip-chip mounting will be described below. Japanese Patent Application Laid-Open No. 2000-188362 discloses an example of mounted structures wherein filler is filled in the portion where a semiconductor element is mounted on a wiring substrate, such as a package, in flip-chip mounting. By this method, the adhesive strength of the filler to the wiring substrate is intensified by forming grooves in the wiring substrate located on the lower portion of the fillet portion formed around the semiconductor element.

Japanese Patent Application Laid-Open No. 2000-277566 discloses an example wherein a bare IC chip is connected to a wiring substrate by electrically conductive particles mixed in the insulating resin of an anisotropic conductive adhesive. This method proposes that by forming a large number of knobs (irregularity) on the outer surface of the fillet of the anisotropic conductive adhesive running off the bare IC chip, low mechanical joint strength or defective electrical connection between the wiring substrate and the electronic parts is prevented before happening.

Japanese Patent Application Laid-Open No. 2005-217005 discloses a resin applying apparatus for applying an underfill resin between a substrate and a face-down mounted semiconductor element. This apparatus is equipped with a nozzle for injecting the underfill resin, and a nozzle moving unit provided so that the nozzle moves along the vicinity of boundary between the semiconductor element and the substrate; and is characterized in that the whole fixing table for fixing the substrate swings synchronizing the movement of the nozzle. The object of this configuration is to evenly apply the resin on the entire surface of the semiconductor chip in a short time.

Japanese Patent Application Laid-Open No. 2007-194403 discloses an apparatus for manufacturing an electronic device wherein the space between a semiconductor chip and a mounting substrate is filled with an underfill agent. This apparatus includes a sensing unit for sensing a fillet portion formed in the underfill agent on the side of the semiconductor chip, and a controlling unit for additionally discharging the underfill agent when the sensed width of the fillet portion is narrower than the proper fillet width.

Japanese Patent Application Laid-Open No. 10-098075 discloses a method for mounting a semiconductor for face-down connecting a semiconductor chip to a wiring substrate. In this method, by applying no solder resist to the site of semiconductor chip mounting so as to widen the space between the semiconductor chip and the wiring substrate, and by using the wiring substrate whose periphery is coated with the solder resist, an insulating resin easily invade into the space to improve the injecting characteristics of the insulating resin.

### SUMMARY

The lidless structure is more advantageous in terms of costs than conventional structures. On the other hand, due to the absence of the lid 18 and the stiffener 17 that is responsible for reinforcement, the lidless structure is relatively fragile to physical deformation and the like. Therefore, under certain conditions, a phenomenon wherein the semiconductor chip 11 or the solder bump 12 is broken (hereafter referred to as “crack”) may occur to cause defects. It is demanded to suppress the defects caused by such reasons, and to raise the reliability of the semiconductor device.

The problems related to the present invention will be described in further detail. In a semiconductor device having a flip-chip structure, a semiconductor chip 11 with the electronic circuit surface facing down is disposed on the wiring substrate 13. FIG. 3 is a schematic diagram showing the semiconductor device having a lidless structure. The semiconductor chip 11 is electrically connected to the wiring substrate 13 by solder bumps 12. The gap between the semiconductor chip 11 and the wiring substrate 13 is filled with the underfill resin 14. The underfill resin 14 is divided into a part to fill the gap between the semiconductor chip 11 and the wiring substrate 13 (hereafter referred to as “under-chip resin 14a”), and a part adhered to the side of the semiconductor chip 11 (hereafter referred to as “fillet 14b”).

When the temperature of the semiconductor device changes, strain and stress as shown in FIG. 4 are generated due to the difference in the coefficient of thermal expansion between the wiring substrate 13 and the semiconductor chip 11. The underfill resin 14 is a thermosetting organic resin with an adjusted coefficient of thermal expansion, and reduces the generated strain and stress by the elasticity of the resin to protect the solder bumps 12.

The underfill resin 14 is injected into the gap between the semiconductor chip 11 and the wiring substrate 13 in the following procedures. An apparatus that has an ability to discharge the resin at a constant rate is used, and the needle 16 that discharges the resin is moved along an optional side of the semiconductor chip 11 to inject the resin (this procedure is hereafter referred to as “I-path”). The injected underfill resin 14 fills the gap between the semiconductor chip 11 and the wiring substrate 13 by capillary phenomenon as shown in FIG. 6. After the under-chip resin 14a has been completely injected, the needle 16 is continuously moved along the entire sides of the semiconductor chip 11 as shown by the arrow in FIG. 7 to inject the resin (this procedure is hereafter referred to as “O-path”). By these procedures, the under-chip resin 14a can be surely injected, and uniform fillets 14b can be formed on the entire sides of the semiconductor chip 11.

The semiconductor device with the lidless structure manufactured by these procedures has a possibility wherein cracks may occur in the semiconductor chip 11 and the fillets 14 causing electrical defects, and further causing the lower yield unless special measures are taken.

When the temperature of the semiconductor device is changed, strain and stress as shown in FIG. 8 occur due to difference in the coefficients of thermal expansion between the semiconductor chip 11 and the wiring substrate 13. In the semiconductor device with lidless structure, a large stress is generated because of the absence of the lid 18 and the stiffener 17 that suppress deformation. Particularly a large stress is applied to the boundary 19 between the semiconductor chip 11 and the fillets 14b as c, and cracks are easily generated. FIG. 9 is a schematic diagram showing a generated crack 15.

This problem can be reduced by changing the material for the underfill resin 14 to lower the tensile stress c. Also by lowering the height of the fillets 14b than the upper surface, which is opposite to the surface where solder balls of the semiconductor chip 11 are provided (this structure is hereafter referred to as “low fillet 14c”), the stress applied to the boundary 19 becomes smaller than the stress generated in the structure shown in FIGS. 8 and 9, and the generation of cracks 15 can be suppressed.

To form the low fillet 14c, the quantity of the underfill resin 14 to be injected must be small. However, because of the procedures for filling the under-chip resin 14a through the I-path, when the quantity of the resin to be injected is simply reduced, the shape of the fillet 14b becomes non-symmetric and non-uniform as shown in FIG. 11. Although the diagram of a low fillet at least bilaterally symmetric is shown in Patent Documents 1 and 5, there is high possibility that the structures are actually non-symmetric. If a structure is non-symmetric and non-uniform, the stress applied to the boundary also becomes non-uniform, and local cracks are produced. As a result of non-uniform structure, the fillet height is lowered, and the side of the interlayer insulating film that constitutes the multilayer wiring structure formed on the circuit-forming side of the chip may be exposed. If the side of the interlayer insulating film, especially the side of the low-permittivity (low-k) film having a relative permittivity lower than the relative permittivity of SiO2 is exposed, defect, such as peeling off, may occur due to the absorption of moisture.

If the method according to Japanese Patent Application Laid-Open No. 2000-277566 for mounting the chip from the upper surface of the underfill resin 14 applied onto the wiring substrate 13 is used in place of the method wherein the underfill resin 14 is injected after mounting the semiconductor chip 11, the height of the fillets 14b can be adjusted by adjusting the quantity of the underfill resin 14. By this method, however, the adhesion between the solder bumps 12 and the wiring substrate 13 tends to be lowered, and reliability tends to be deteriorated.

Therefore, a method and an apparatus for manufacturing a highly reliable semiconductor device having a lidless flip-chip structure are required.

The method for solving the problems will be described using reference numerals with parentheses used in “Detailed Description of the Preferred Embodiments”. These reference numerals are added for clarifying the correspondence relationship between descriptions in “Claims” and “Detailed Description of the Preferred Embodiments”. However, these reference numerals should not be used for translating the technical scope of the invention described in “Claims”.

A method for manufacturing a semiconductor device is a method for manufacturing a semiconductor device wherein an underfill resin (14) is filled in a space between a substrate (13) and a semiconductor chip (11), including injecting a first underfill resin in said space under a first injecting condition; specifying a location where the fillet height (b) of the underfill resin formed on the side of said semiconductor chip does not meet a prescribed standard; and injecting a second underfill resin in a location where the fillet height (b) does not meet the prescribed standard under a second injecting condition.

An apparatus for manufacturing a semiconductor device according to the present invention is an apparatus for manufacturing a semiconductor device (30) wherein an underfill resin (14) is filled in a space between a substrate (13) and a semiconductor chip (11), and includes a sensing unit (33) for sensing the fillet height (b) of the underfill resin formed on the side of the semiconductor chip; a specifying unit (38) for specifying a location where the fillet height b does not meet a prescribed standard; and an additional-injecting condition selecting unit (39) for selecting the injecting condition when the underfill resin is additionally injected to the specified location depending on the detected height of the fillet (b) so that the fillet height (b) meets the prescribed standard.

According to the present invention, since a semiconductor device adjusted so that the fillet height of the underfill resin meets the prescribed standard is manufactured, there are provided a method and an apparatus for manufacturing a reliable semiconductor device that suppresses the concentration of stress caused by difference in the coefficient of thermal expansion between the semiconductor chip and the wiring substrate, and has a lidless flip-chip structure.

According to the present invention, a method and an apparatus for manufacturing a reliable semiconductor device having a lidless flip-chip structure is provided.

### DETAILED DESCRIPTION OF THE PREFERRED EMBODIMENTS

The preferred embodiments for carrying out the present invention will be described in detail below referring the drawings.

### First Embodiment

FIG. 12 is a sectional view showing a semiconductor device according to the first embodiment viewed from the side. The semiconductor device has a flip-chip structure and a lidless structure. Solder balls 22 used for electrical connection are fixed on the rear surface of a wiring substrate 13. A semiconductor chip 11 is flip-chip connected to the surface of the wiring substrate 13 via solder bumps 12. An underfill resin 14 is injected into the gap between the surface of the wiring substrate 13 and the rear surface of the semiconductor chip 11 for protecting the solder bumps 12. The underfill resin 14 coats the side of the semiconductor chip 11. The upper end of the underfill resin 14 is lower than the upper surface of the semiconductor chip 11. Specifically, the fillet formed by the underfill resin 14 on the side of the semiconductor chip 11 is a low fillet 14c. The height b of the low fillet 14c is not more than 80% the height a of the semiconductor chip 11, and is evenly controlled on all the sides of the semiconductor chip 11 (four sides of the semiconductor chip that has a square plane shape).

When the temperature of a semiconductor device changes, the device is deformed and generates strain and stress due to difference in coefficients of thermal expansion of the materials. Since the low fillet 14c is formed lower and smaller than the high fillet (fillet 14b shown in FIG. 8), the stress c generated between the low fillet 14c and the semiconductor chip 11 is smaller than the stress generated by the semiconductor device having a high-fillet structure. Thereby, the possibility of crack generation between the chip and the fillet is lowered, and the possibility of electrical damage of the semiconductor device is suppressed. As a result, the reliability of the semiconductor device can be improved.

The effect achieved by the first embodiment will be described below. Although the underfill resin 14 is prepared so as to have a coefficient of thermal expansion close to the coefficient of thermal expansion of silicon that constitutes the semiconductor chip 11, the underfill resin 14 has a coefficient of thermal expansion higher than the coefficient of thermal expansion of silicon for securing fluidity or the like. Therefore, when the semiconductor device is heated, compressive stress e is generated in the location of the semiconductor chip 11 shown in FIG. 13. On the other hand, at a low temperature, tensile stress c is generated in the location shown in FIG. 8. These stresses intensify as the semiconductor chip 11 becomes larger, and especially becomes higher at the corners of the semiconductor chip 11.

The crack 15 is mainly produced at a low temperature, and rupture as shown in FIG. 14 is generated to produce the crack 15. The produced crack 15 expands to the electronic-circuit surface 20, and may also reach the solder bumps 12 and the wiring substrate 13 depending on the location. If such matters happen, the semiconductor device is electrically damaged and broken.

The tensile stress c applied to the semiconductor chip 11 depends on the height of the fillet. As a result of the simulation of stress by the inventors of the present application, it was clarified that the stress was lowered by 2% when the height b of the fillet was lowered by 17% than the height a of the chip. Also, the lower limit of the fillet height is preferably a height to cover at least the side of the interlayer insulating film that constitutes a multilayer wiring structure formed on the circuit-forming surface of the chip. Particularly, when a low-k film having a relative permittivity lower than the relative permittivity of SiO2 is formed, it is preferable that at least the side of the low-k film is covered.

### Second Embodiment

The second embodiment will be described referring to FIG. 15. In the second embodiment, the semiconductor device has a flip-chip structure and a lidless structure. The semiconductor chip 11 is electrically connected to the wiring substrate 13 by solder bumps 12. The underfill resin 14 is injected to protect solder bumps 12 using the following procedures.

An under-chip resin 14a is injected using the I-path. An underfill resin 14 is injected into only the portion where the underfill resin 14 shown in FIG. 2 has not formed sufficient low fillets 14c (hereafter referred to as “resin-insufficient portion 21”) to form uniform low fillets 14c on all the sides of the semiconductor chip 11.

The under-chip resin 14a is injected using the capillary phenomenon through the I-path. At this time, a part of the underfill resin 14 forms the low fillets 14c on the side of the semiconductor chip 11. As a result, a non-symmetric structure wherein the portion where low fillets 14c are sufficiently formed and the portion where low fillets 14c are insufficiently formed are mixed as shown in FIG. 15.

Therefore, by injecting the underfill resin 14 only into the resin-insufficient portion 21 to selectively form the low fillets 14c in the resin-insufficient portion 21, uniform low fillets 14c can be formed on all the sides of the semiconductor chip 11. By combining a method for injecting the underfill resin 14 using an ink-jet system in addition to the needle 16, the injection of the underfill resin 14 into the resin-insufficient portion 21 can be controlled more accurately instead of using the needle 16, and low fillets 14c of higher quality can be formed.

When the underfill resin 14 is injected using the I-path, low fillets 14c are formed on a part of the sides of the semiconductor chip 11 as the under-chip resin 14a is injected. The low fillets 14c are easily formed on the side where the underfill resin 14 has been injected, and poorly formed on the facing side and the vicinities of the corners of the chip.

When the formation of the fillet 14b is intended, the uniform fillet 14b is formed on all the sides of the semiconductor chip 11 by injecting the underfill resin using the O-path after injecting the under-chip resin 14a. However, if the quantity of the underfill resin 14 of the O-path is reduced for the formation of the low fillets 14c, the low fillets 14c are formed in the resin-insufficient portion 21, and the previously formed low fillets 14c becomes higher to be the fillet b, and as a whole, non-uniform structure wherein the fillet 14b and the low fillet 14c are mixed is formed.

By performing injection of the underfill resin 14 limited to the resin-insufficient portion 21 in place of injection into the entire semiconductor chip 11 using the O-path, the low fillets 14c can be selectively formed in the resin-insufficient portion 21 while maintaining previously formed low fillets 14c, and uniform fillets 14c can be formed on all the sides of the semiconductor chip 11.

By using the method for manufacturing a semiconductor device according to the second embodiment, a semiconductor device according to the first embodiment can be easily fabricated.

The following effects can be achieved by the first and second embodiments:
1. Since stress applied to the semiconductor chip 11 and the fillets 14b with change in temperatures can be reduced, the occurrence of the crack 15 is prevented, and the quality of the semiconductor device is improved.
2. Uniform low fillets 14c can be easily formed on all the sides of the semiconductor chip 11 that realizes the above-described objects.
3. The injecting quantity of the underfill resin can be minimized, and the material costs can be reduced.

### Third Embodiment

The third embodiment will be described referring to FIGS. 16 to 20. FIG. 16 shows an application work 22, which is a subject to which an underfill resin is applied according to the third embodiment. The application work 22 is formed by connecting a semiconductor chip 11 on a wiring substrate 13 via solder bumps 12.

FIG. 17 shows the configuration of an apparatus for manufacturing 30 a semiconductor device according to the third embodiment of the present invention. The apparatus for manufacturing 30 is equipped with an applying unit 32 that supplies the underfill resin 14 into the gap between the semiconductor chip 11 and the wiring substrate 13 from the end of a side of the semiconductor chip 11 while moving along a set path; a sensing unit 33 that senses the height of the fillet 14b of the underfill resin 14 from the wiring substrate 13; and a computer that sets up the path and the injecting condition s to control the applying unit 32.

The underfill resin 14 is applied to the application work 22 as shown in FIG. 18. At this time, a temporary condition (injecting condition A) is set up as the injecting condition 35. In the injecting condition A, at least one resin application is set up for the formation of uniform low fillet 14c. The controlling unit 31 controls the applying unit 32 according to the injecting condition A. After applying the resin, the application work 22 is subjected to heat treatment to cure the underfill resin 14, and the fillet 14b is completed as shown in FIG. 19.

After the underfill resin 14 has been cured, the sensing unit 33 observes the application work 22 from the side, and measures the height of the fillet 14b. The specifying unit 38 is a functional block to specify the characteristics of the fillet height, and classifies the fillet 14b into any of the normal fillet 14d, the uniform low fillet 14c, and the non-uniform low fillet 14e shown in FIGS. 20A to 20C, respectively on the basis of previously registered standard as the height standard 36, from the measured height of the fillet 14b and the previously set height of the semiconductor chip 11.

The normal fillet 14d is characterized in that a part of or the entire fillet 14 is higher than the semiconductor chip 11. In this case, since the quantity of the underfill resin 14 set up in the injecting condition A is excessive, the specifying unit 38 changes the injecting condition A so as to decrease the quantity of the resin, and registers the changed injecting condition A as the injecting condition 35.

The uniform low fillet 14c is characterized in that the height of the entire fillet 14b is smaller than the height of the semiconductor chip 11, and the height of the entire fillet 14b is uniform.

The non-uniform low fillet 14e is characterized in that the height of the entire fillet 14b is smaller than the height of the semiconductor chip 11, and the height of the entire fillet 14b is non-uniform. In this case, since the resin is deficient at a specified location, the additional-injecting condition selecting unit 39 estimates the location and quantity of the deficient resin, newly establishes or changes the injecting condition to compensate for insufficient resin (injecting condition B), and registers the condition as the additional the conditions as the additional injecting condition 37. The one or a plurality of resin applications set up for compensating the resin-deficient location under the injecting condition A.

When the injecting condition B is set up or changed, the controlling unit 31 controls the applying unit 32 so as to inject the underfill resin 14 again as shown in FIG. 18 using the application work 22 before injecting the underfill resin 14. At this time, injection using the injecting condition B is performed after injection using the injecting condition A. After application has been completed, heat treatment is performed to cure the resin, and the height of the fillet 14b is measured. If the fillet 14b is classified into the normal fillet 14d or the non-uniform low fillet 14e as a result of the measurement, the injecting condition A is replaced by the injecting condition B.

The above-described procedures are repeated until the uniform fillet 14c is completed. The combination of the injecting condition A and the injecting condition B when the uniform low fillet 14c is formed is referred to as the injecting condition C. By applying the underfill resin 14 to the application work 22 using the injecting condition C, uniform low fillets 14c can be continuously formed.

### Fourth Embodiment

A method for manufacturing a semiconductor device according to the fourth embodiment can be realized by applying an apparatus for manufacturing equivalent to the third embodiment. In the same manner as in the description using FIG. 18, the underfill resin 14 is applied onto the application work 22. At this time, a temporary condition (injecting condition A) is used as the injecting condition. In the injecting condition A, at least one resin application is set up for the formation of uniform low fillet 14c.

After the resin has been applied, the quantity of the underfill resin 14 applied onto the application work 22 is measured using a measuring apparatus 23 as shown in FIG. 21. The measuring apparatus 23 is an apparatus having functions to observe the application work 22 from the side, and measure the height to which the underfill resin 14 reaches at one or more locations.

From the results of height measurement of the underfill resin 14, the measuring apparatus 23 automatically classify the quantities of the resin on the application work 22 into excessive, deficient, and appropriate.

When the resin quantity if excessive, the formation of the normal fillet 14d is estimated. Since the treatment according to the fourth embodiment cannot automatically respond to the normal fillet 14d, the measuring apparatus 23 reports prescribed outputs to the operator. When the operator receives the report, the operator changes the injecting condition A so that the resin quantity becomes deficient or appropriate, and carries out the resin applying shown in FIG. 18 again.

When the resin quantity is deficient, the formation of the non-uniform low fillet 14e is estimated. In this case, the region where the resin quantity is deficient and the deficient quantity are determined from the measurement result, and a resin injecting condition (injecting condition B) for compensate the deficient resin is selected. On the basis of the result of determination, the underfill resin 14 is applied to the region where the resin quantity is deficient using the injecting condition B as shown in FIG. 22. The determination and additional resin applying are automatically performed. By carrying out the treatment once or more, the resin quantity becomes appropriate.

When the resin quantity is appropriate, the formation of the uniform low fillet 14c is estimated. In this case, the following process is carried out without performing additional applying.

By previously setting up the injecting condition A so that the resin quantity does not become excessive, the uniform low fillets 14c can be automatically continuously formed by the above-described treatment.

### BRIEF DESCRIPTION OF THE DRAWINGS

FIG. 1 is a schematic diagram showing a semiconductor device that has a flip-chip structure according to a background art;

FIG. 2 is a schematic diagram showing a (lidless) semiconductor device that has a flip-chip structure according to a background art;

FIG. 3 is a schematic diagram showing a semiconductor device that has a lidless structure;

FIG. 4 is a diagram showing the deformation of a semiconductor device that has a flip-chip structure due to change in temperatures;

FIG. 5 is a schematic diagram showing the injection of an underfill resin 14 through an I-path;

FIG. 6 is a diagram showing an under-chip resin 14a injected through the I-path;

FIG. 7 is a diagram showing the injection of an underfill resin 14 through an O-path;

FIG. 8 is a diagram showing a stress generated by the deformation of a semiconductor device according to a background art due to change in temperatures;

FIG. 9 is a schematic diagram showing a crack 15 produced by a stress c;

FIG. 10 is a diagram showing a stress generated by the deformation of a semiconductor device due to change in temperatures;

FIG. 11 is a diagram showing a nonuniform low fillet 14c;

FIG. 12 is a schematic diagram showing a semiconductor device that has a flip-chip structure and a low-fillet structure;

FIG. 13 is a diagram showing a stress e generated by the deformation of a semiconductor device due to change in temperatures;

FIG. 14 is a schematic diagram showing a crack 15 produced by a stress c (during deformation);

FIG. 15 is a diagram showing an additional resin injection for forming a uniform fillet shape;

FIG. 16 is a diagram showing an applying work;

FIG. 17 is a diagram showing the configuration of an apparatus for manufacturing a semiconductor device;

FIG. 18 is a diagram showing the application of the underfill resin under injecting condition s A;

FIG. 19 is a diagram showing the state of a completed fillet;

FIGS. 20A to 20C are diagrams showing the aspects of fillets;

FIG. 21 is a diagram showing the measurement of the height of a fillet; and

FIG. 22 is a diagram showing the application of the underfill resin under injecting conditions B.

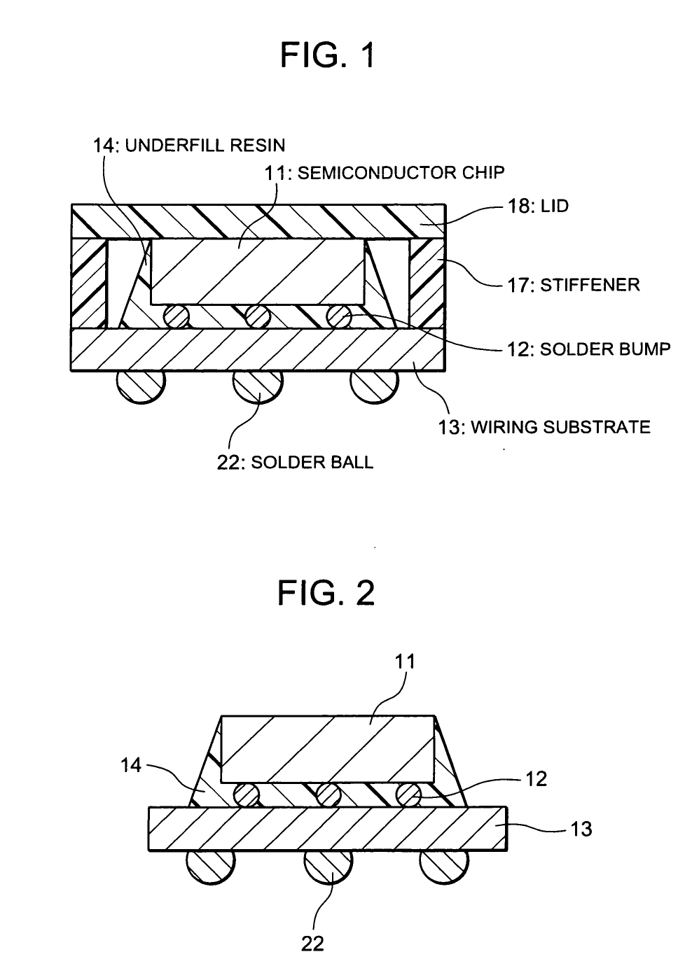

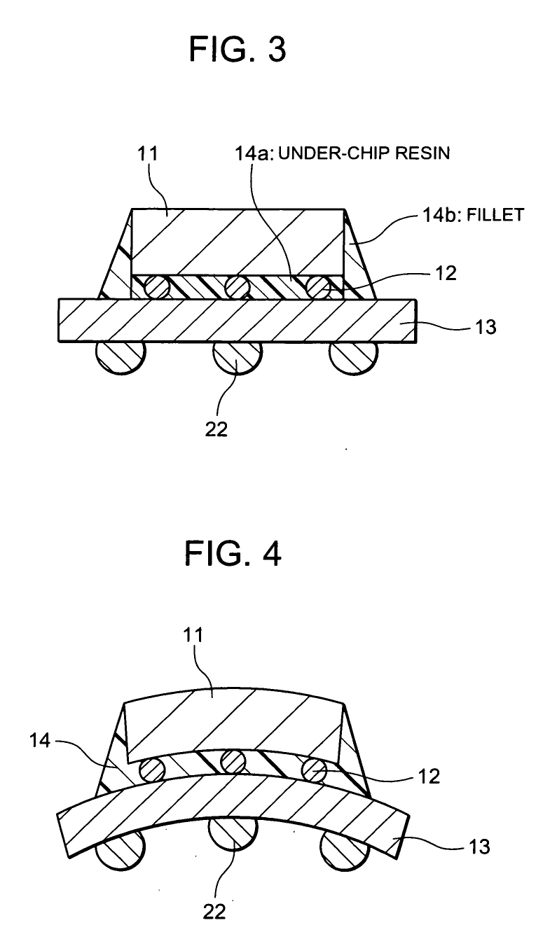

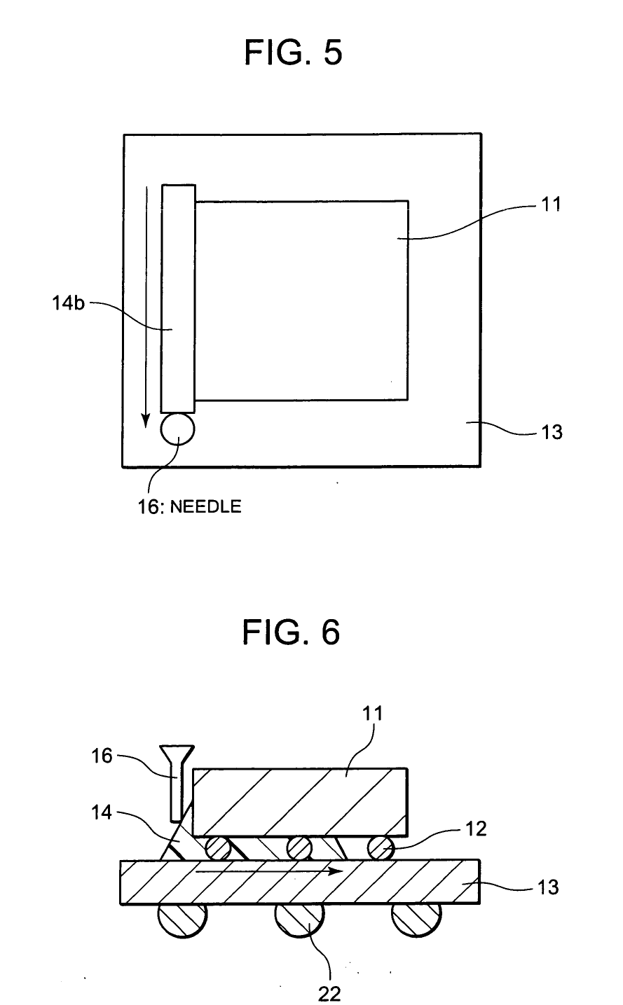

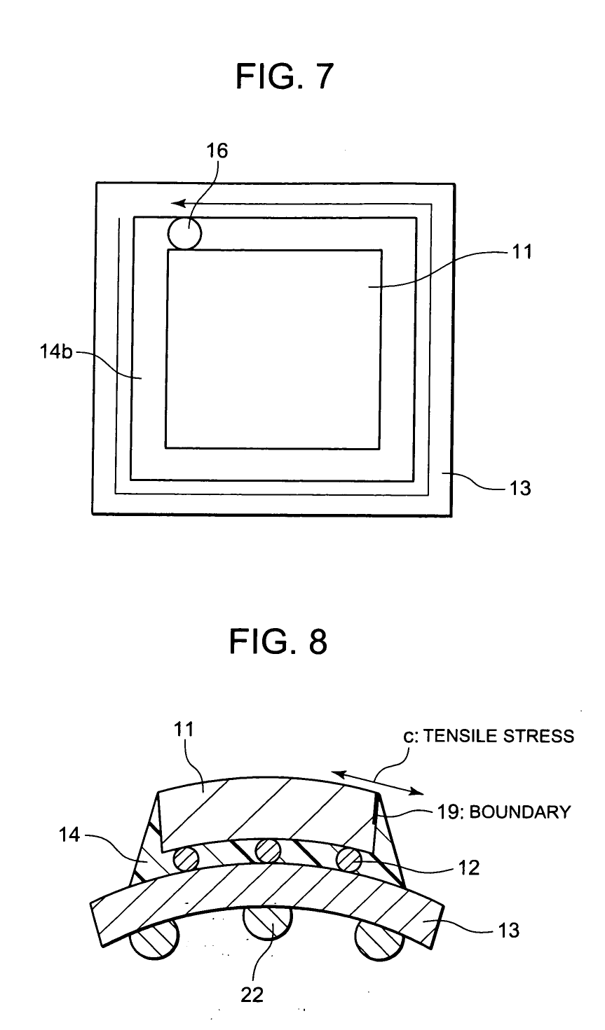

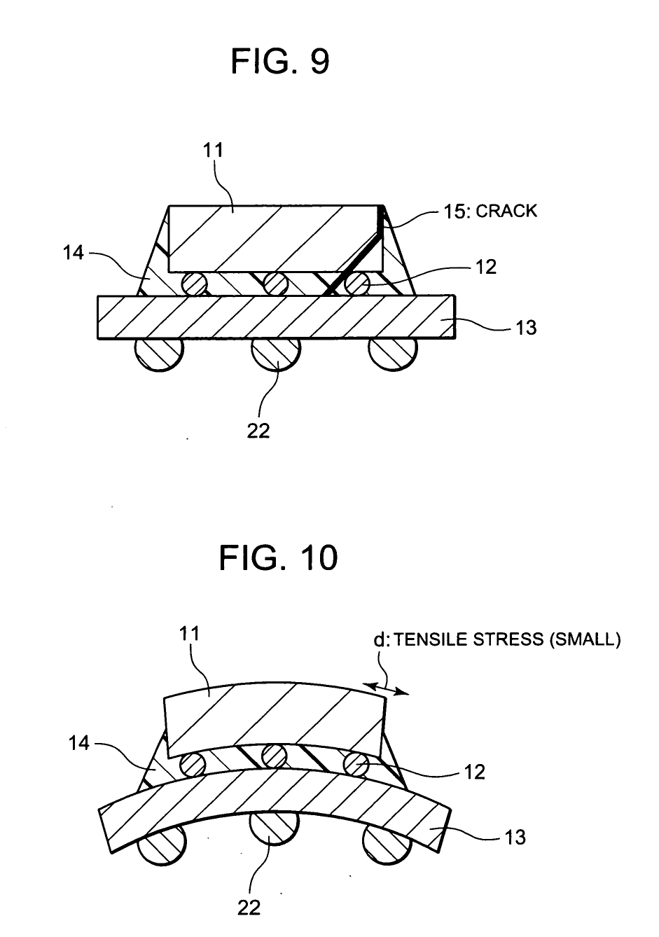

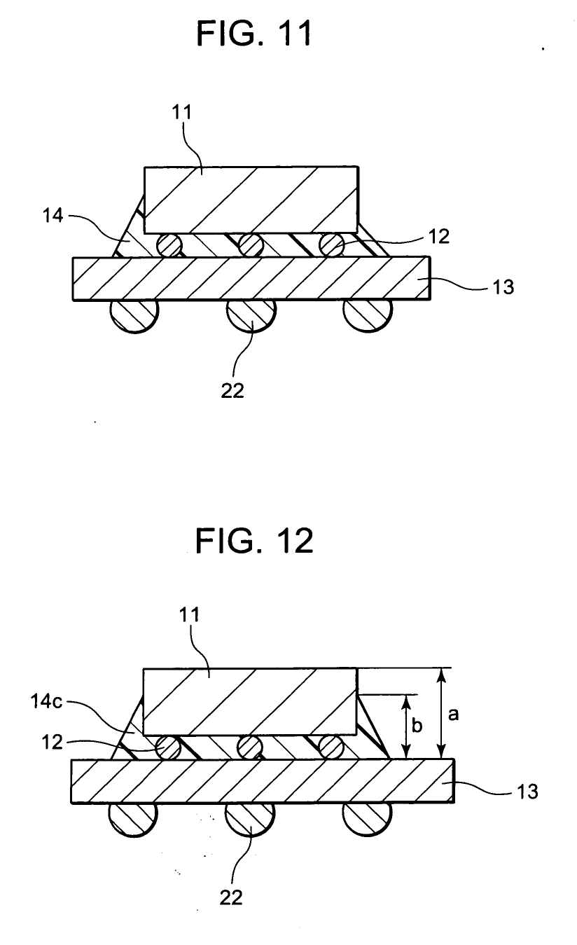

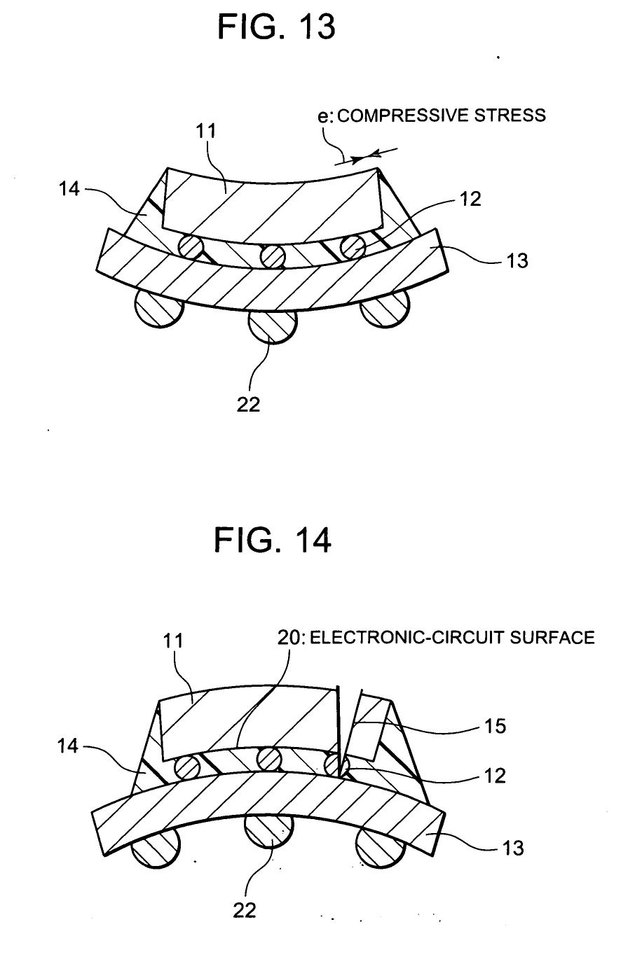

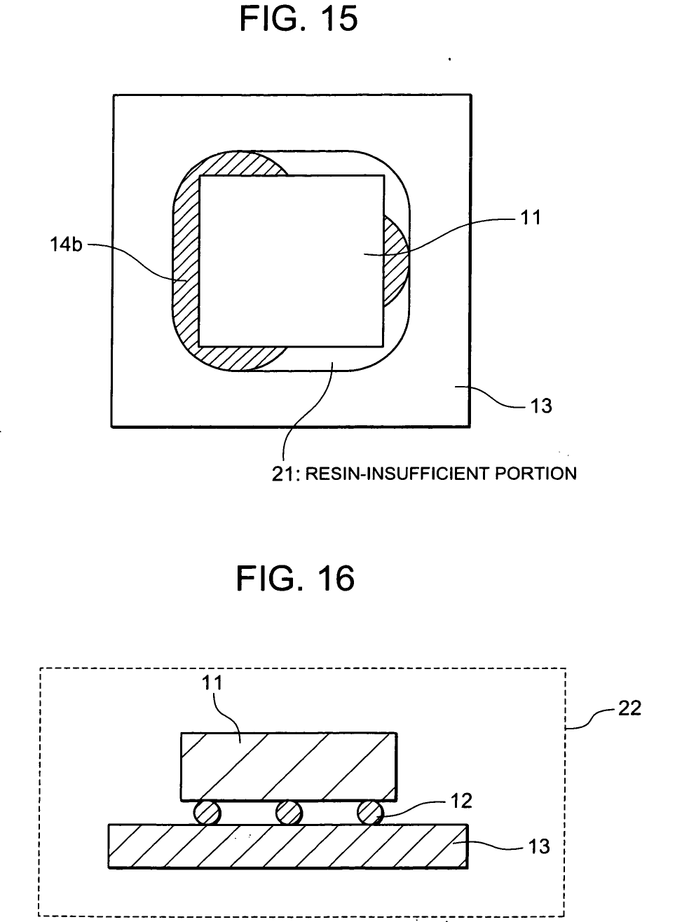

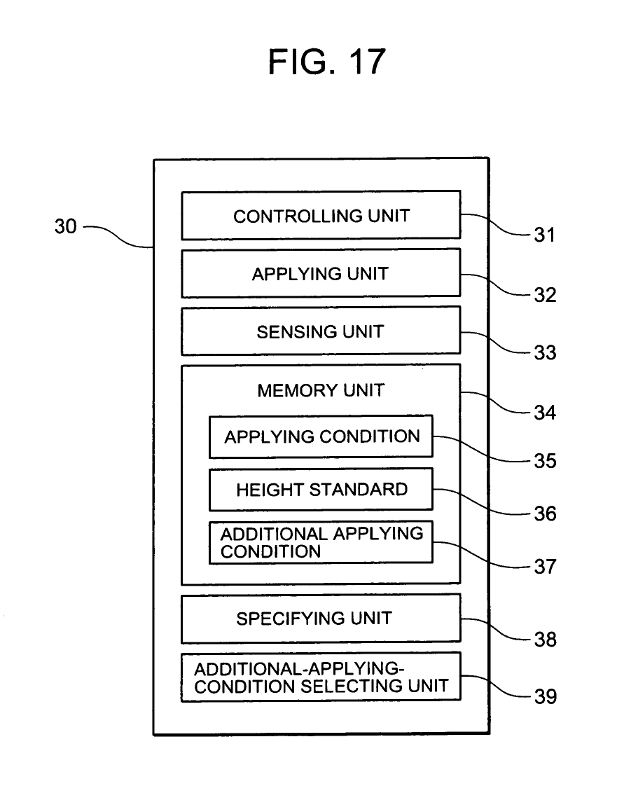

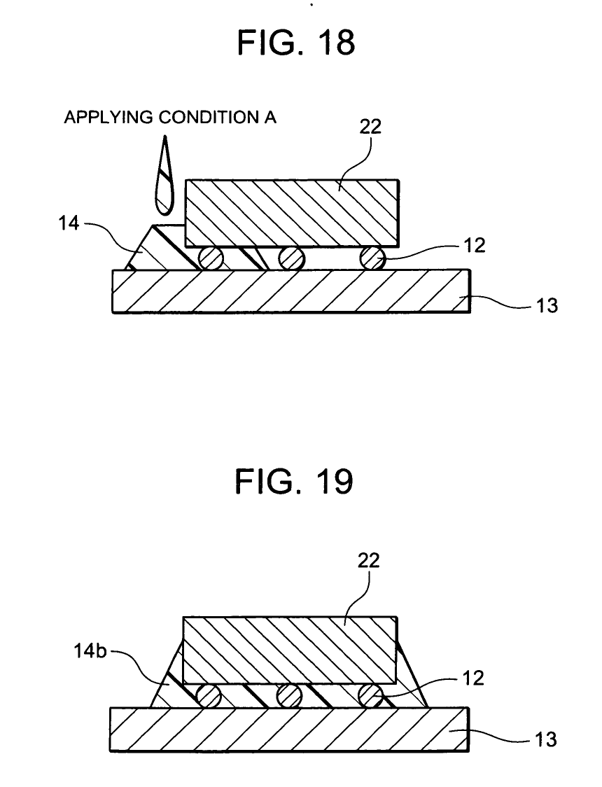

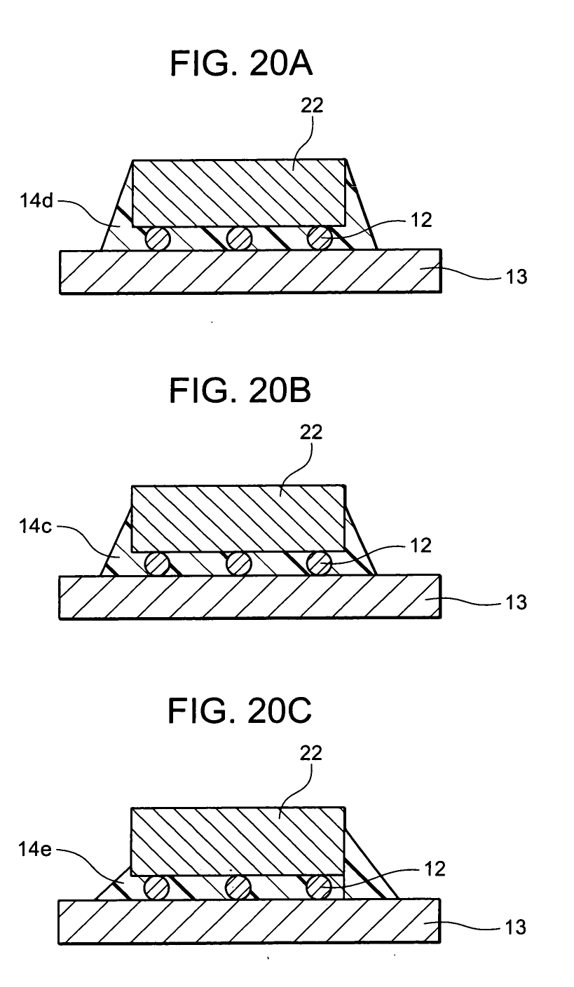

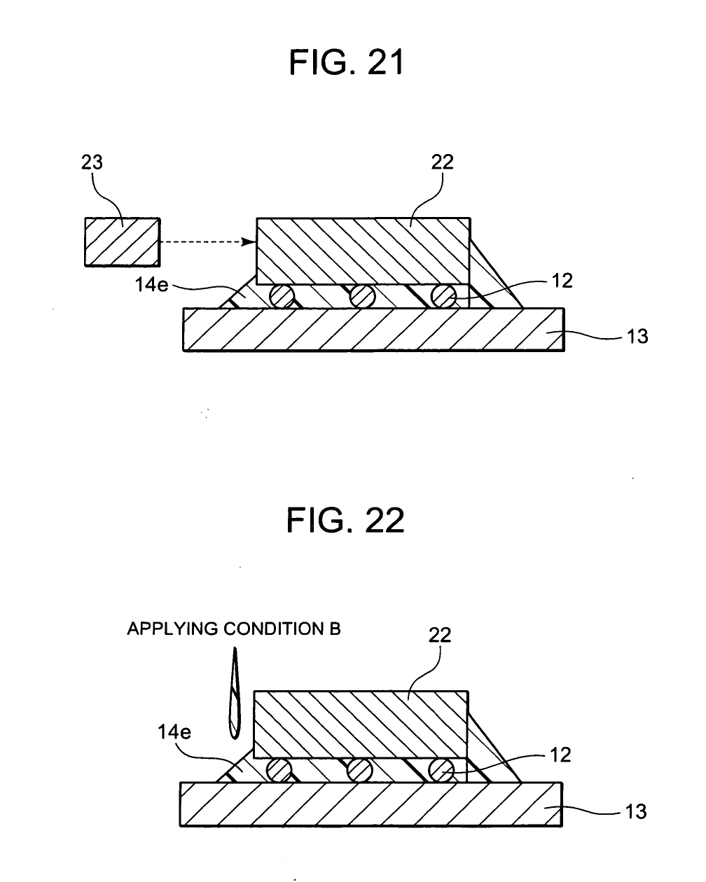

What is claimed is:

1. A method for manufacturing a semiconductor device wherein an underfill resin is filled in a space between a substrate and a semiconductor chip, comprising:
injecting a first underfill resin in said space under a first injecting condition;
specifying a location where the fillet height of the underfill resin formed on the side of said semiconductor chip does not meet a prescribed standard; and
injecting a second underfill resin in a location where the fillet height does not meet the prescribed standard under a second injecting condition.

2. The method for manufacturing a semiconductor device according to claim 1, wherein said prescribed standard requires that said fillet height does not exceed the prescribed height set up to be lower than the height of the upper surface of said semiconductor chip.

3. The method for manufacturing a semiconductor device according to claim 2, wherein said prescribed height is at least 17% lower than the height of said semiconductor chip.

4. The method for manufacturing a semiconductor device according to claim 2, wherein said prescribed height is a height to cover at least an interlayer insulating film that composes a multilayer wiring structure formed on the circuit-forming plane of said semiconductor chip.

5. The method for manufacturing a semiconductor device according to claim 4, wherein the relative permittivity of said interlayer insulating film is lower than the relative permittivity of SiO2.

6. The method for manufacturing a semiconductor device according to claim 1, wherein injecting the underfill resin in said space under a first injecting condition is for injecting said underfill resin by moving a needle, which is a nozzle for ejecting said underfill resin, along a side of said semiconductor chip.

7. The method for manufacturing a semiconductor device according to claim 1, injecting the underfill resin in a location where the fillet height does not meet the prescribed standard under a second injecting condition is for injecting said underfill resin using an inkjet system.

8. The method for manufacturing a semiconductor device according to claim 3, wherein said semiconductor chip is flip-chip-mounted on sad substrate before said first injecting step; and
said semiconductor device has no lid on the upper surface of said semiconductor chip.

9. The method for sequentially manufacturing a plurality of said semiconductor devices according to claim 1, wherein injecting the underfill resin in said space under a first injecting condition is the same for any of the semiconductor devices.

10. An apparatus for manufacturing a semiconductor device wherein an underfill resin is filled in a space between a substrate and a semiconductor chip, comprising:
a sensing unit for sensing the fillet height of the underfill resin formed on the side of said semiconductor chip;
a specifying unit for specifying a location where said fillet height does not meet a prescribed standard; and
an additional-injecting-condition selecting unit for selecting the injecting condition when said underfill resin is additionally injected to the specified location depending on the detected height of the fillet so that said fillet height meets said prescribed standard.
